(19) United States
(12) Patent Application Publication
(10) Pub. No.: US 2024/0113232 A1
(43) Pub. Date: Apr. 4, 2024

(54) EXTENDED EPITAXIAL GROWTH FOR IMPROVED CONTACT RESISTANCE

(71) Applicant: INTERNATIONAL BUSINESS MACHINES CORPORATION, Armonk, NY (US)

(72) Inventors: Daniel Schmidt, Niskayuna, NY (US); Ruilong Xie, Niskayuna, NY (US); Alexander Reznicek, Troy, NY (US); Tsung-Sheng Kang, Ballston Lake, NY (US)

(21) Appl. No.: 17/956,309

(22) Filed: Sep. 29, 2022

(51) Int. Cl. H01L 29/786; H01L 29/06

(52) U.S. Cl. CPC H01L 29/78696; H01L 29/0665

(57) ABSTRACT

A semiconductor device that includes a stack of sheet semiconductor layers, and source and drain regions positioned on opposing sides of a channel region in the stack of sheet semiconductor layers. A first contact is present to an upper sheet portion of the source and drain regions for the stack of sheet semiconductor layers. An extended epitaxial semiconductor region is present in contact with the lower sheet portion of the source/drain regions for the stack of sheet semiconductor layers. A second contact is present in direct contact with an upper surface of the extended epitaxial semiconductor region. A notch may be present in the upper surface of the extended semiconductor region to increase contact surface to the second contact.

### BACKGROUND

The present disclosure relates to semiconductor devices, and more particularly to contacts to source and drain regions of semiconductor devices nanosheets.

With the continuing trend towards miniaturization of integrated circuits (ICs), there is a need for transistors to have higher drive currents with increasingly smaller dimensions. The use of non-planar semiconductor devices such as, for example, nanosheet transistors is one step in the evolution of complementary metal oxide semiconductor (CMOS) devices.

However, in some instances as device size continues to increase, as contacts are formed to smaller features sizes increased contact resistance can reduce performance.

### SUMMARY

In one embodiment, a semiconductor device is provided includes a nanosheet device having low resistance contacts to the source and drain regions. In some embodiments, to provide reduced contact resistance, an extended epitaxial semiconductor region is present in contact with the lower portion of the source/drain regions. The extended epitaxial region provides a larger contact surface for the contact in electrical communication with the lower portion of the source and drain regions.

In one embodiment, the semiconductor device includes a stack of sheet semiconductor layers. Source and drain regions are positioned on opposing sides of a channel region in the stack of sheet semiconductor layers. A first contact is present to an upper sheet portion of the source and drain regions for the stack of sheet semiconductor layers. An extended epitaxial semiconductor region is present in contact with the lower sheet portion of the source/drain regions for the stack of sheet semiconductor layers. A second contact is present in direct contact with an upper surface of the extended epitaxial semiconductor region.

In another embodiment, to provide reduced contact resistance, the extended semiconductor region further includes a notch in its upper surface. In this embodiments, the notch provides both a sidewall surface and a base surface of the notch as the interface with to the contract which increases the direct contact of the surfaces between the extended epitaxial semiconductor region and the contact. In one embodiment, the semiconductor device includes a stack of sheet semiconductor layers. Source and drain regions are positioned on opposing sides of a channel region in the stack of sheet semiconductor layers. A first contact is present to an upper sheet portion of the source and drain regions for the stack of sheet semiconductor layers. An extended epitaxial semiconductor region is present in contact with the lower sheet portion of the source/drain regions for the stack of sheet semiconductor layers. The extended epitaxial semiconductor region includes an upper surface with a notch. A second contact is present in direct contact with the notch in the upper surface of the extended epitaxial semiconductor region, wherein the second contact is in direct contact with both a sidewall surface and a base surface of the notch.

In another aspect, a method of forming a semiconductor device is provided that includes a nanosheet device having low resistance contacts to the source and drain regions. In some embodiments, to provide reduced contact resistance, an extended epitaxial semiconductor region is formed in contact with the lower portion of the source/drain regions. The extended epitaxial region provides a larger contact surface for the contact in electrical communication with the lower portion of the source and drain regions.

In one embodiment, the method includes forming a stack of sheet semiconductor layers. Source and drain regions are formed on opposing sides of a channel region in the stack of sheet semiconductor layers. A first contact is formed to an upper sheet portion of the source and drain regions for the stack of sheet semiconductor layers. An extended epitaxial semiconductor region is epitaxially deposited in contact with the lower sheet portion of the source/drain regions for the stack of sheet semiconductor layers. A second contact is formed in direct contact with an upper surface of the extended epitaxial semiconductor region.

In some embodiments, prior to forming the second contact, the upper surface of the extended epitaxial semiconductor region can be etched to provide a notch. The notch provides a sidewall surface and base surface for the second contact to be formed in direct contact with. The incorporation of the sidewall surface and the base surface of the notch provides increased surface area for the interface between the extended epitaxial semiconductor region and the second contact, which decreases the resistance of the contact.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 illustrates a nanosheet device including two contacts to the source/drain regions of the device, in which the contact to the lower sheet portion of the nanosheet stack device includes an extended epitaxial semiconductor region that provides a larger contact surface for the contact that is in electrical communication with the lower portion of the source and drain regions.

FIG. 2 is a side cross-sectional view of a nanosheet device including two contacts to the source/drain regions of the device, in which the contact to the lower sheet portion of the nanosheet stack device includes an extended epitaxial semiconductor region having an upper surface with a notch that provides for increased contact surface for the contact that is in electrical communication with the lower portion of the source and drain regions.

FIG. 3 is a top down view illustrating the different cross-sections described throughout the present disclosure including the source/drain cross-section that is depicted in FIGS. 1 and 2.

FIG. 4 is a side cross-sectional view along a source/drain cross-section illustrating a nanosheets stack having two regions of different stack heights and bottom sheet source/drain epitaxy material, and a sacrificial spacer material formed atop the nanosheet stacks.

FIG. 5 is a side cross-sectional view illustrating forming an opening in the sacrificial spacer material illustrated in FIG. 4 to expose a portion of the upper sheet portion for the stack of sheet semiconductor layers for the source and drain regions, in accordance with one embodiment of the present disclosure.

FIG. 6 is a side cross-sectional view illustrating forming a top sheet epitaxy that encompasses the top nanosheet assembly of the nanosheet stack in the opening depicted in FIG. 5, in accordance with one embodiment of the present disclosure.

FIG. 7 is a side cross-sectional view illustrating removing the sacrificial spacer material depicted in FIG. 6, in accordance with one embodiment of the present disclosure.

FIG. 8 is a side cross-sectional view illustrating forming a sidewall spacer on the assembly of the top sheet epitaxial semiconductor material and dielectric contact cap, in accordance with one embodiment of the present disclosure.

FIG. 9 is a side cross-sectional view illustrating forming an extended epitaxial semiconductor region that extends to a bottom nanosheet source/drain epitaxy material, in accordance with one embodiment of the present disclosure.

### DETAILED DESCRIPTION

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

In one aspect, embodiments of the present disclosure describe structures and methods of semiconductor devices having an extended bottom epitaxy for improved contact resistance in stacked field effect transistor (FET). The integration scheme for contacts to stacked field effect transistors (FETs) employs a deep via etch for the contact to the lower sheets of the source and drain regions of nanosheet stacked devices. Due to the taper inherent in etch processing for via openings, the deeper the via opening is formed the narrower the base of the via opening gets. Therefore, in some embodiments, a deep via opening will have a small base area. In applications in which the via is being formed to source/drain regions, this results in a small contact area. A small contact area can result in high contact resistance, which can reduce device performance.

In some embodiments, a semiconductor device is provided includes a stacked nanosheet device having low resistance contacts to the source and drain regions. The term “nanosheet” denotes a substantially two dimensional structure with thickness in a scale ranging from 1 to 100 nm. The width and length dimensions of the nanosheet may be greater than the thickness dimension. Source/drain regions are disposed on opposite sides of the channel region.

In some embodiments, to provide reduced contact resistance, an extended epitaxial semiconductor region is present in contact with the lower portion of the source/drain regions. The extended epitaxial semiconductor region provides a larger contact surface for the contact in electrical communication with the lower portion of the source and drain regions.

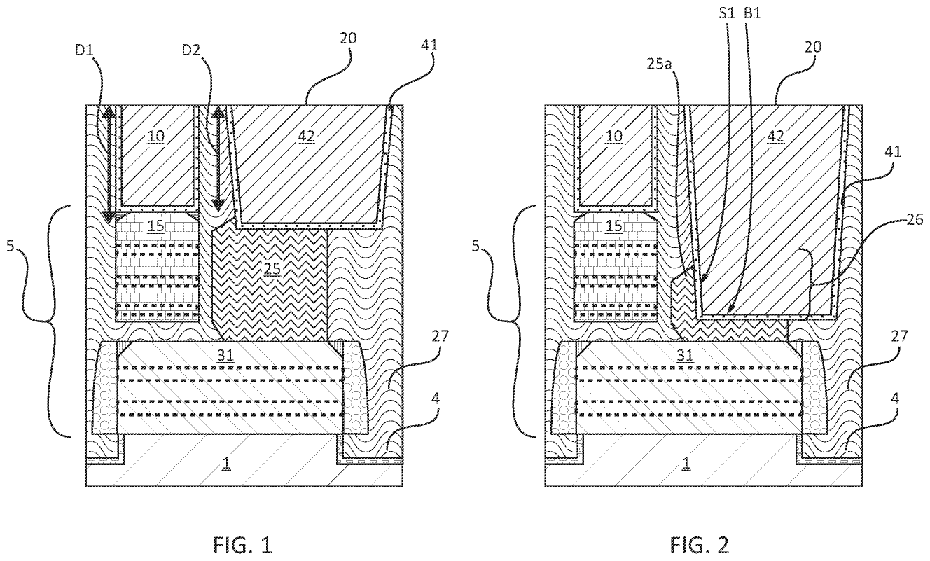

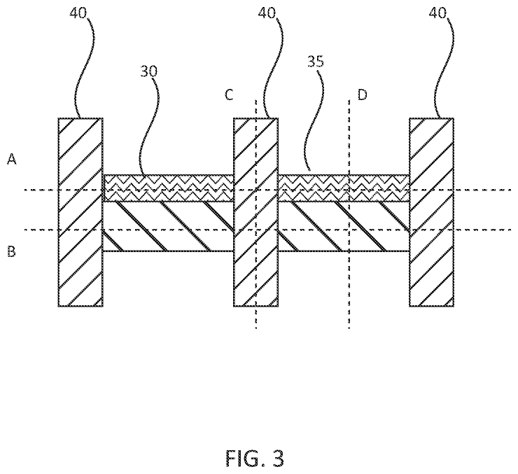

As will be described in further detail below, the stacked nanosheet devices described herein can have two contacts to the source/drain regions, as depicted in FIGS. 1-3. FIG. 3 is a top down view illustrating the different cross-sections that are used to describe the structures and methods of the present disclosure. FIGS. 1 and 2 are side cross-sectional view along section line D-D as depicted in FIG. 3. This cross-section is referred to as a source/drain cross-section.

Referring to FIG. 1, a first contact 10 is to the portion of the source/drain regions corresponding with the upper nanosheet layers of the nanosheet stack. The first contact 10 may be in contact with a top sheet epitaxy 15 that encompasses around the top nanosheet assembly of the nanosheet stack 5. A second contact 20 is also present that includes an assembly of an extended epitaxial semiconductor region 25 that extends to a bottom sheet source/drain epitaxy material 31, wherein the extended epitaxial semiconductor region 25 extends above the nanosheet assembly 15. In this embodiment, the bottom sheet epitaxy may be composed of two different materials, e.g., doping levels and/or species, which can be formed using a two step process.

In the embodiment that is depicted in FIG. 1, the extended epitaxial semiconductor region 25 and the top sheet epitaxy 15 have substantially the same height. Therefore, the contacts to the extended epitaxial semiconductor region 25 and the top sheet epitaxy 15, i.e., the second contact 20 and first contact 10, respectively, have substantially the same depth D2, D1.

Referring to FIGS. 1 and 3, in one embodiment, the semiconductor device 100 includes a stack of sheet semiconductor layers 5. Source and drain regions 30, 35 are positioned on opposing sides of a channel region in the stack of sheet semiconductor layers 5. Referring to FIG. 1, a first contact 10 is present to an upper sheet portion of the source and drain regions 30, 35 for the stack of sheet semiconductor layers. More specifically, the first contact 10 is in direct contact with a top sheet epitaxy 15 that is in direct contact with the upper sheet portion of the nanosheet stack 15 for the source and drain regions 30, 35. An extended epitaxial semiconductor region 25 is present in contact with the lower sheet portion of the source/drain regions 30, 35 for the stack of sheet semiconductor layers. A second contact 20 is present in direct contact with an upper surface of the extended epitaxial semiconductor region 25. Similar to the first contact 10, the second contact 20 is in direct contact with the extended epitaxial semiconductor region 25, in which the extended epitaxial semiconductor region 25 is in direct contact with a bottom sheet source/drain epitaxy material 31. The bottom sheet source/drain epitaxy material 31 is in direct contact with the lower sheets of the nanosheet stack 5. The nanosheet stack that is illustrated in FIGS. 1-3 is a staircase type arrangement. This indicates that the nanosheet stack 5 has two regions of different heights, i.e., one region having a height greater than the other.

In another embodiment, to provide reduced contact resistance, the extended semiconductor region further includes a notch in its upper surface, as depicted in FIGS. 2 and 3. In this embodiments, the notch 26 provides both a sidewall surface S1 and a base surface B1 as the interface with the contact 20, which increases the direct contact of the surfaces between the extended epitaxial semiconductor region 25a and the contact 20a. In some embodiments, improved contact resistance is provided by having the metal contact, i.e., contact 20a, protrude into the extended bottom epitaxy, i.e., extended epitaxial semiconductor region 25a.

Referring to FIG. 2, in one embodiment, the semiconductor device 100b includes a stack of sheet semiconductor layers 5. Similar to the embodiment described with reference to FIG. 1, the stack of sheet semiconductor layers 5 includes two regions of different height, e.g., the sack of sheet semiconductor layers 5 has as staircase arrangements. Referring to FIGS. 2 and 3, source and drain regions 30, 35 are positioned on opposing sides of a channel region in the stack of sheet semiconductor layers 5. A first contact 10 is present to an upper sheet portion of the source and drain regions 30, 35 for the stack of sheet semiconductor layers 15. More specifically, the first contact 10 is in direct contact with a top sheet epitaxy 15 that is in direct contact with the upper sheet portion of the nanosheet stack 5 for the source and drain regions 30, 35. An extended epitaxial semiconductor region 25a is present in contact with the lower sheet portion of the source/drain regions 30, 35 for the stack of sheet semiconductor layers 5. Similar to the first contact 10, a second contact 20a is in direct contact with the extended epitaxial semiconductor region 25a, in which the extended epitaxial semiconductor region 25a is in direct contact with a bottom sheet source/drain epitaxy material 31. The extended epitaxial semiconductor region 25a includes an upper surface with a notch 26. The second contact 20a is present in direct contact with the notch 26 in the upper surface of the extended epitaxial semiconductor region 25a. The second contact 20a is in direct contact with both a sidewall surface S1 and a base surface B1 of the notch 26.

FIG. 3 further illustrates the presence of a gate structure 40 on a channel region portion of the nanosheet stack 5 between the source and drain regions 30, 35 for the semiconductor devices 100a, 100b depicted in FIGS. 1 and 2. A “gate structure” means a structure used to control output current (i.e., flow of carriers in the channel) of a semiconducting device. The gate structure 40 includes a gate dielectric that is present on the channel region portion of the nanosheet stack 5, and a gate conductor that is present on the gate dielectric.

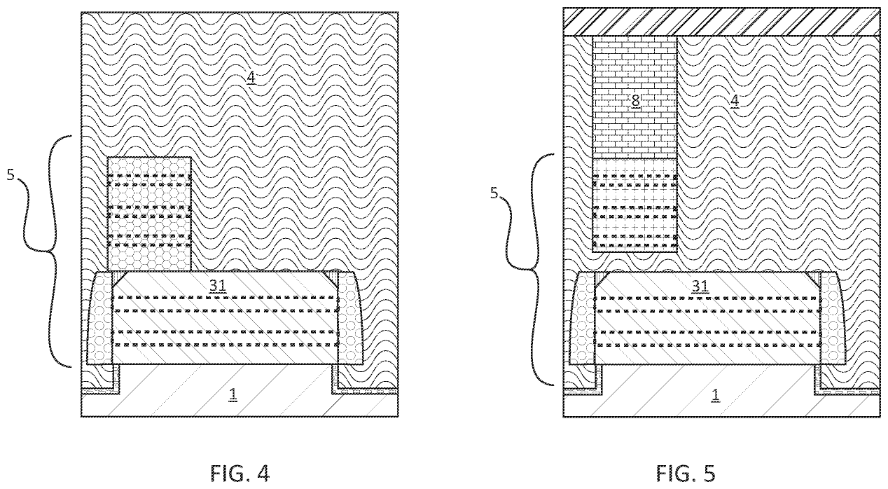

Further details regarding the structures depicted in FIGS. 1-3 are now described in a description for some embodiments of methods for forming the structures described above with reference FIGS. 4-9.

FIG. 4 illustrates one embodiment of an initial structure that can be used for forming the contact assemblies to the source/drain regions 30, 35 of the semiconductor devices 100a, 100b that are illustrated in FIGS. 1-3.

FIG. 4 illustrates one embodiment of a nanosheet stack 5 along a source/drain cross section. The nanosheet stack 5 depicted in FIG. 3 has a geometry that is provided by a staircase process flow. By “staircase” it is meant that the stack includes at least two nanosheet stack heights. For example, the stack height H1 for a first portion of the nanosheet stack 5 may include a greater number of nanosheets than the stack height H2 for a second portion of the nanosheet stack 5. The first portion of the nanosheet stack 5 having the first stack height H1 may be contacted by the first contact 10, and may provide the portion of the nanosheet stack 5 that provides the upper sheet portion of the nanosheet stack 5. The second portion of the nanosheet stack 5 having the second stack height H2 may be contacted by the second contact 20, 20a, and may provide the portion of the nanosheet stack 5 that provides the lower sheet portion of the nanosheets stack 5.

Each of the nanosheets in the nanosheets stacks 5 may be composed of a type IV semiconductor composition and/or III-V semiconductor composition. For example, the compositions selected for the layers within the stacks of layered semiconductor materials for the nanosheet stacks 5 can include Si, SiGe, SiGeC, SiC, single crystal Si, polysilicon, i.e., polySi, epitaxial silicon, i.e., epi-Si, amorphous Si, i.e., a:Si, germanium, gallium arsenide, gallium nitride, cadmium telluride, zinc selenide, and combinations thereof.

It is noted that the stack of nanosheets 5 depicted in FIG. 4 is only one example of a nanosheet stack 5. The claimed methods and structures are not limited to only this example, as stacks having a greater or lesser number of nanosheets than those depicted in FIG. 4 are within the scope of the present disclosure. For example, the number of nanosheets in either regions of the nanosheet stacks 15 may also be equal to 3, 4, 5, 10, 15 and 20, as well as any value between the aforementioned examples.

The stack of nanosheets 5 may be formed using a deposition process, such as epitaxial deposition. “Epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

It is noted that to provide that the nanosheets are suspended above a supporting substrate 5, the nanosheets may be formed in a sequence with sacrificial semiconductor materials that are present between the nanosheets. Following deposition of the stack, the sacrificial semiconductor materials may be removed, wherein the nanosheets remain suspended over the substrate 1. In some embodiments, spacers (not shown) may aid in the support for the suspended nanosheets. To provide different heights H1, H2 for the nanosheets stacks 5 etch processes in combination with photolithography and photoresist/hard masks may be employed.

As noted above, the stack of nanosheets 5 may be present over a substrate 1. The substrate 1 may be composed of a supporting material, such as a semiconductor material, e.g., silicon, or dielectric material, such as silicon oxide or silicon nitride.

It is noted that the initial structure may also include epitaxial source and drain regions 30, 35 (as well as a gate structure 40 (as depicted in FIG. 4) is formed on opposing ends of the channel portions of the stack of nanosheets 15. The epitaxial source and drain regions 30, 35 may be composed of a semiconductor material that is doped to provide the conductivity type of the device. The semiconductor material for the epitaxial source and drain regions 30, 35 may be composed of a type IV and/or type III/V semiconductor material.

As used herein, the term “drain” means a doped region in semiconductor device located at the end of the channel region, in which carriers are flowing out of the transistor through the drain. The term “source” is a doped region in the semiconductor device, in which majority carriers are flowing into the channel region.

The epitaxial semiconductor material can be grown on sidewall surfaces of the nanosheets 15. In some embodiments, the epitaxial semiconductor material may be composed of silicon (Si), germanium (Ge), silicon germanium (SiGe), silicon doped with carbon (Si:C) or the epitaxial semiconductor material may be composed of a type III-V compound semiconductor, such as gallium arsenide (GaAs).

Epitaxial deposition may be carried out in a chemical vapor deposition apparatus, such as a low pressure chemical vapor deposition (LPCVD) apparatus, plasma enhanced chemical vapor deposition (PECVD) apparatus, atmospheric pressure chemical vapor apparatus.

The epitaxial semiconductor material for the source and drain regions 30, 35 may be in situ doped to a p-type or n-type conductivity. As used herein, the term “conductivity type” denotes a dopant region being p-type or n-type. As used herein, “p-type” refers to the addition of impurities to an intrinsic semiconductor that creates deficiencies of valence electrons. In a silicon-containing material, examples of n-type dopants, i.e., impurities, include but are not limited to boron, aluminum, gallium and indium. As used herein, “n-type” refers to the addition of impurities that contributes free electrons to an intrinsic semiconductor. In a silicon containing material examples of n-type dopants, i.e., impurities, include but are not limited to antimony, arsenic and phosphorous. The dopants may be introduced to the semiconductor material for the epitaxial semiconductor material that provides the source and drain regions by in situ doping.

The term “in situ” denotes that a dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses. In other embodiments, the semiconductor material for the source and drain regions 30, 35 may be doped by ion implantation. It is noted that the material of the source and drain regions 30, 35 is illustrated by the bottom sheet source/drain epitaxy material 31 in FIG. 4.

FIG. 4 further illustrates a sacrificial spacer material 4 that is present atop the stack of nanosheets 5. The sacrificial spacer material 4 can be a dielectric material. For example, the sacrificial spacer material 4 can be an oxide, such as silicon oxide. In other embodiments, the sacrificial spacer material 4 can be a nitride, such as silicon nitride.

It is noted that the initial structure depicted in FIG. 4 may further include a gate structure 40, as depicted in FIG. 3. The gate structure 40 may be formed using gate first or gate last processing. Gate last refers to a gate structure forming process using a replacement gate. By “replacement” it is meant that the structure is present during processing of the semiconductor device, but is removed from the semiconductor device prior to the device being completed. In a gate last process flow, a replacement gate structure is employed as part of a replacement gate process. As used herein, the term “replacement gate structure” denotes a sacrificial structure that dictates the geometry and location of the later formed functioning gate structure. The “functional gate structure” operates to switch the semiconductor device from an “on” to “off” state, and vice versa.

As noted above with reference to FIGS. 1-3, the functional gate structure, i.e., gate structure 40, may include a gate dielectric and a gate conductor.

FIG. 5 illustrates one embodiment forming an opening 8 in the sacrificial spacer material 4 to expose a portion of the upper sheet portion for the stack of sheet semiconductor layers 15 for the source and drain regions 30, 35.

Forming the opening 8 can include deposition, photolithography and etching. In one embodiments, forming the openings 8 can begin with forming a photoresist etch mask. Specifically, in one example, a photoresist mask is formed overlying the sacrificial spacer material 4. The exposed portions of the sacrificial spacer material 4 that are not protected by the photoresist mask are removed using a selective etch process to provide the openings 8. To provide the photoresist mask, a photoresist layer is first positioned on the sacrificial spacer material 4. The photoresist layer may be provided by a blanket layer of photoresist material that is formed utilizing a deposition process such as, e.g., plasma enhanced CVD (PECVD), evaporation or spin-on coating.

The blanket layer of photoresist material is then patterned to provide the photoresist mask utilizing a lithographic process that may include exposing the photoresist material to a pattern of radiation and developing the exposed photoresist material utilizing a resist developer. Following the formation of the photoresist mask, an etching process may remove the unprotected portions of the sacrificial spacer material 4 to provide the opening 8. The etch process may be an anisotropic process. The term “anisotropic etch process” denotes a material removal process in which the etch rate in the direction normal to the surface to be etched is greater than in the direction parallel to the surface to be etched. The anisotropic etch may include reactive-ion etching (RIE). Other examples of anisotropic etching that can be used at this point of the present disclosure include ion beam etching, plasma etching or laser ablation.

The etch process may be selective to the stack of nanosheets 15. As used herein, the term “selective” in reference to a material removal process denotes that the rate of material removal for a first material, e.g., sacrificial spacer material 4, is greater than the rate of removal for at least another material, e.g., the nanosheets of the stack of nanosheets 15, of the structure to which the material removal process is being applied.

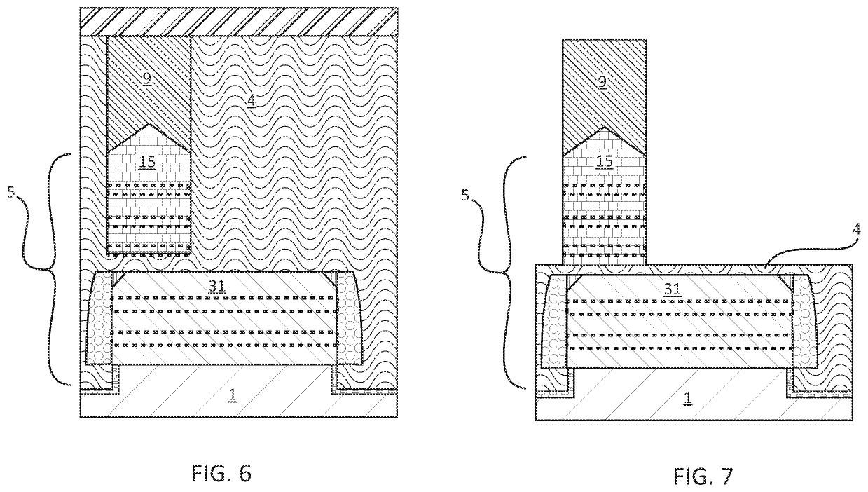

FIG. 6 illustrates one embodiment of forming a top sheet epitaxy 15 that encompasses the top nanosheet assembly of the nanosheet stack in the opening depicted in FIG. 5. The top sheet epitaxy source/drain 15 is formed in the opening using an epitaxial deposition process and may be composed of any type IV and/or type III-V semiconductor material. The top sheet epitaxy 15 may be grown on sidewall surfaces of the top nanosheets. In some embodiments, the epitaxial semiconductor for the top sheet epitaxy 15 material may be composed of silicon (Si), germanium (Ge), silicon germanium (SiGe), silicon doped with carbon (Si:C) or the epitaxial semiconductor material may be composed of a type III-V compound semiconductor, such as gallium arsenide (GaAs).

Epitaxial deposition may be carried out in a low pressure chemical vapor deposition (LPCVD) apparatus, plasma enhanced chemical vapor deposition (PECVD) apparatus, atmospheric pressure chemical vapor deposition (APCVD) apparatus, or metal organic chemical vapor deposition (MOCVD) apparatus or a plasma enhanced chemical vapor deposition (PECVD) apparatus.

The epitaxial semiconductor material for the top sheet epitaxy 15 may be in situ doped to a p-type or n-type conductivity. The above description of n-type and p-type dopants for the source and drain regions 30, 35 is suitable for the dopants for the top sheet epitaxy 15. The dopants may be introduced to the semiconductor material for the epitaxial semiconductor material that provides the top sheet epitaxy 15 by in situ doping. The dopant that provides the conductivity type in the top sheet epitaxy 15 has a greater doping concentration than the dopant that provides the conductivity type in the bottom sheet source/drain epitaxy material 31.

Following the formation of the epitaxial semiconductor material for the top sheet source/drain epitaxy 15 in the opening 8, the remainder of the opening 8 may be filled with a dielectric material for a sacrificial dielectric contact cap 9. The sacrificial dielectric contact cap 9 may be composed of a dielectric that is a metal oxide, such as titanium oxide (TiOₓ). It is noted that the aforementioned example is provided for illustrative purposes, and that the present disclosure is not intended to be limited to this example composition. The material for the sacrificial dielectric contact cap 9 may be formed using any deposition process, e.g., chemical vapor deposition. Following filling of the opening 8 with the sacrificial dielectric contact cap 9, a planarization process, such as chemical mechanical planarization (CMP) is applied to the structures upper surface to provide that the upper surface of the sacrificial dielectric contact cap 9 is coplanar with the upper surface of the sacrificial spacer material 4.

FIG. 7 depicts one embodiment of removing the sacrificial spacer material 4. The spacer strip depicted in FIG. 7 may be provided by a wet chemical etch or strip or cleaning process. In other embodiments, the sacrificial spacer material 4 is removed by a dry etch process. The etch process selected for removing the sacrificial spacer material 4 is selective to at least the bottom sheet source/drain epitaxy material 31, the top sheet epitaxy 15, and the stack of nanosheets 5.

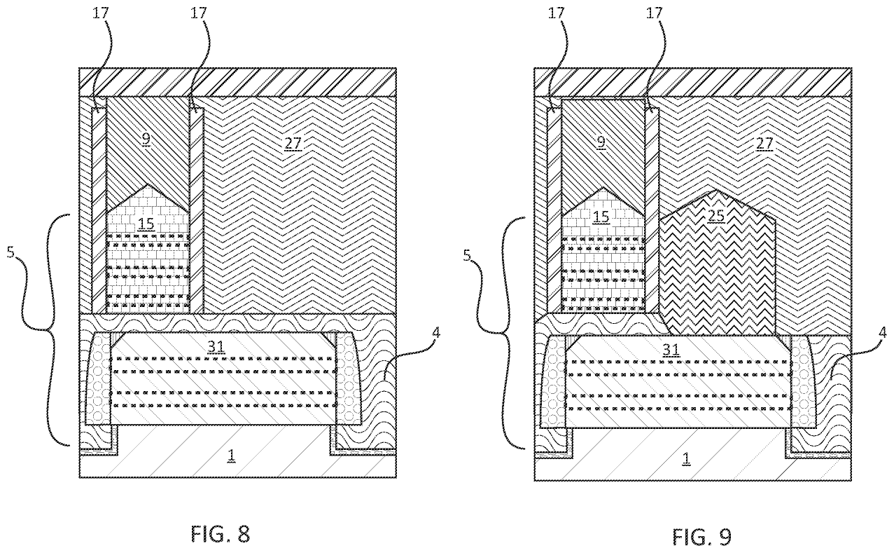

FIG. 8 depicts forming a sidewall spacer 17 on the assembly of the top sheet epitaxial semiconductor material 15 and the sacrificial dielectric contact cap 9. The sidewall spacer 17 may be composed of a dielectric material, such as an oxide, nitride, or oxynitride material. In one example, when the sidewall spacer 17 is composed of a nitride, the sidewall spacer 17 may be composed of silicon nitride, and when the sidewall spacer 17 is composed of oxide, the sidewall spacer 17 may be composed of silicon oxide. The sidewall spacer 17 may be formed using a deposition process, such as chemical vapor deposition (CVD), and an anisotropic etch back method. The sidewall spacer 17 may be present on the sidewalls of the top sheet epitaxial semiconductor material 15 and the sacrificial dielectric contact cap 9, and may have a thickness ranging from 4 nm to 15 nm.

FIG. 9 illustrates one embodiment of forming an extended epitaxial semiconductor region 25 that extends to a bottom nanosheet source/drain epitaxy material 31. In one embodiment, prior to depositing the extended epitaxial semiconductor region 25, any remaining material from the sacrificial spacer material 4 that is present atop the bottom nanosheet source/drain epitaxy material 31 may be removed. In some embodiments, any remaining material from the sacrificial spacer material 4 that is present atop the bottom nanosheet source/drain epitaxy material 31 is removed using a selective etching process. Following exposing the upper surface of the bottom nanosheet source/drain epitaxy material 31, an epitaxial deposition process is employed for forming the extended epitaxial semiconductor region 25 directly on the upper surface of the bottom nanosheet source/drain epitaxy material 31.

The extended epitaxial semiconductor region 25 may be composed of any type IV or type III-V semiconductor material. For example, the extended epitaxial semiconductor region 25 may be composed of silicon (Si), germanium (Ge), silicon germanium (SiGe), silicon doped with carbon (Si:C) or the epitaxial semiconductor material may be composed of a type III-V compound semiconductor, such as gallium arsenide (GaAs). Epitaxial deposition may be carried out in a chemical vapor deposition apparatus, such as alow pressure chemical vapor deposition (LPCVD) apparatus, plasma enhanced chemical vapor deposition (PECVD) apparatus, atmospheric pressure chemical vapor apparatus.

The epitaxial semiconductor material for the extended epitaxial semiconductor region 25 may be in situ doped to a p-type or n-type conductivity. In a silicon-containing material, examples of n-type dopants, i.e., impurities, include but are not limited to: boron, aluminum, gallium and indium. In a silicon containing material examples of n-type dopants, i.e., impurities, include but are not limited to antimony, arsenic and phosphorous. The dopants may be introduced to the semiconductor material for the epitaxial semiconductor material that provides the source and drain regions by in situ doping.

The dopant that provides the conductivity type in the extended epitaxial semiconductor region 25 has a greater doping concentration than the dopant that provides the conductivity type in the bottom sheet source/drain epitaxy material 31.

Referring back to FIG. 1, the method may continue with removing the sidewall spacer 17, forming an interlevel dielectric layer 27 to a height that covers at least the sacrificial dielectric contact cap 9, and planarizing the structure, e.g., by chemical mechanical planarization (CMP) to provide that the upper surface of the sacrificial contact cap 9 is coplanar with the upper surface of the planarized interlevel dielectric layer 27.

The sidewall spacer 17 and the sacrificial dielectric cap 9 may each be removed using an etch process, such as elective etch.

The intralevel dielectric layer 27 may be selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The interlevel dielectric layer 27 may be deposited by chemical vapor deposition (CVD), physical vapor deposition (PVD), spin on deposition, deposition from solution or a combination thereof.

Still referring to FIG. 1, in a following process, the interlevel dielectric layer 27 may be patterned and etched to provide a via opening to the extended epitaxial semiconductor region 25. In the embodiment that is described with reference to FIG. 1, the via opening to the extended semiconductor region 25 includes similar deposition, photolithography and etch processes as those used to form the opening 8 to expose a portion of the upper sheet portion for the stack of sheet semiconductor layers 15 for the source and drain regions 30, 35 that is described above with reference to FIG. 5. Therefore, the description of forming the opening 8 for the structure depicted in FIG. 5 is suitable for forming the opening to the extended semiconductor region.

The embodiment depicted in FIG. 1 places the emphasis on providing a tall epitaxial material for the extended semiconductor region 25, to provide that the contact has similar height at the top nanosheet sheet epitaxy 15. This allows for easier middle of the line (MOL) integration.

In some embodiments, termination of the etch process for forming the opening to the extended semiconductor region 25 may include end point detection. The etch process is selected to provide that the extended epitaxial semiconductor region 25 and the top sheet epitaxy 15 have substantially the same height. In this embodiment, the contacts to the extended epitaxial semiconductor region 25 and the top sheet epitaxy 15, i.e., the second contact 20 and first contact 10, respectively, have substantially the same depth D2, D1. It is noted that terminating the etch for forming the opening to the extended epitaxial semiconductor region 25 is optional.

FIG. 2 illustrates another embodiment of the present disclosure, in which the etch process for forming the opening does not terminate on the upper surface of the extended epitaxial semiconductor region 25. The embodiment depicted in FIG. 2 can provide a focus on low contact resistance. In the embodiment depicted in FIG. 2, the etch process for forming the opening through the interlevel dielectric layer 27 to the extended epitaxial semiconductor region 25, etches through the upper surface of the extended epitaxial semiconductor region 25 to form a notch 26 in the upper surface of the extended epitaxial semiconductor region 25. In FIG. 2 following the formation of the notch, the extended epitaxial semiconductor region is identified by reference number 25a. The notch 26 exposes a sidewall surface S1 and base surface B1 of the upper surface of the epitaxial semiconductor region 25a, in which the sidewalls Si exposed by the notch 26 can increase the contact area of the interface between the extended epitaxial semiconductor region 25 and the second contact 20a. In one example, the sidewall Si height can range from 4 nm to 25 nm. Additionally, the extended etch can reduce the amount of epitaxial semiconductor material that separates the contact 20a from the bottom sheet source/drain epitaxy material 31. This increase in contact area in some instances can decrease contact resistance by magnitudes of 4X.

The etch process for forming the opening to the extended epitaxial semiconductor region 25, and in some embodiments etching the notch 26 in the upper surface of the extended epitaxial semiconductor material 25a (FIG. 2), can include an anisotropic etch process, such as reactive ion etching (RIE).

Referring to FIGS. 1 and 2, following forming the opening to the extended epitaxial semiconductor material 25, and forming the notch 26 in the upper surface of the extended epitaxial semiconductor material 25a (as depicted in FIG. 2), the method may continue with forming the first and second contacts 10, 20.

Forming the first and second contacts 10, 20 may include depositing a liner material 41 on the sidewalls and the base of the openings to each of the extended epitaxial semiconductor region 25, 25a and the top nanosheet sheet epitaxy 15. The liner material 41 may have a composition for a seed layer, adhesion layer of barrier layer. In some embodiments, the liner material 41 may be composed of copper (Cu), cobalt (Co), tantalum (Ta), tantalum nitride (TaN), tungsten nitride (WN), titanium (Ti), titanium nitride (TiN), molybdenum nitride (MoN), tungsten silicon nitride (WSiN), tungsten silicon (WSi), Nb, NbN, Cr, CrN, TaC, TaCeO₂, TaSiN, TiSiN, and combinations thereof. The liner material 41 can be formed by physical vapor deposition, e.g., sputtering; plating, e.g., electroplating or electroless plating; by chemical vapor deposition, e.g., metal organic chemical vapor deposition (MOCVD) and/or plasma enhanced chemical vapor deposition (PECVD); atomic layer deposition (ALD) or a combination thereof.

Following the formation of the liner material 41, the openings to each of the extended epitaxial semiconductor region 25, 25a and the top nanosheet sheet epitaxy 15 may be filled with a fill 42 for the first and second contacts 10 that can be provided by any suitable conductive material(s), such as tungsten, copper, aluminum, platinum, silver, gold, tantalum, tantalum nitride, ruthenium, titanium, and combinations thereof. The metal materials for the fill 42 for the first and second contacts 10 can be formed by physical vapor deposition, e.g., sputtering; plating, e.g., electroplating or electroless plating; by chemical vapor deposition, e.g., metal organic chemical vapor deposition (MOCVD) and/or plasma enhanced chemical vapor deposition (PECVD); or a combination thereof. Following deposition of the fill 42, the upper surface of the structure may be planarized using chemical mechanical planarization (CMP).

Having described preferred embodiments of a methods and structures to extended epitaxial growth for improved contact resistance disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising:
a stack of sheet semiconductor layers;
a source region and a drain region positioned on opposing sides of a channel region in the stack of sheet semiconductor layers;
a first contact to an upper sheet portion of the source and drain regions for the stack of sheet semiconductor layers;
an extended epitaxial semiconductor region in contact with a lower sheet portion of a source/drain region portion for the stack of sheet semiconductor layers; and
a second contact in direct contact with an upper surface of the extended epitaxial semiconductor region.

2. The semiconductor device of claim 1, wherein the sheet semiconductor layers are nanosheets.

3. The semiconductor device of claim 2, wherein the sheet semiconductor layers a first region of nanosheets at a first height and a second region of nanosheets at a second height, wherein the second height is less than the first height, the upper sheet portion that the first contact is in contact with is in the first region, and the lower sheet portion that the second contact is in contact with is in the second region.

4. The semiconductor device of claim 1, wherein the lower sheet portion is a bottom sheet source/drain epitaxy material.

5. The semiconductor device of claim 4, wherein the extended epitaxial semiconductor region has a higher dopant concentration for n-type or p-type dopant than the bottom sheet source/drain epitaxy material.

6. The semiconductor device of claim 1, wherein the upper sheet portion of the source and drain regions is an upper sheet epitaxy semiconductor material that is doped to an n-type or p-type conductivity.

7. The semiconductor device of claim 1, wherein the upper sheet epitaxy semiconductor material and the extended epitaxial semiconductor region have a substantially same height from a supporting substrate underlying the stack of sheet semiconductor materials.

8. The semiconductor device of claim 1, wherein the first contact and the second contact have substantially a same depth.

9. A semiconductor device comprising:
a stack of sheet semiconductor layers;
a source region and a drain region positioned on opposing sides of a channel region in the stack of sheet semiconductor layers;
a first contact to an upper sheet portion of the source and drain regions for the stack of sheet semiconductor layers;
an extended epitaxial semiconductor region in contact with a lower sheet portion of a source/drain region portion for the stack of sheet semiconductor layers, the extended epitaxial semiconductor region includes an upper surface with a notch; and
a second contact in direct contact with an upper surface of the extended epitaxial semiconductor region, wherein the second contact is in direct contact with both a sidewall surface and a base surface of the notch.

10. The semiconductor device of claim 9, wherein the sheet semiconductor layers are nanosheets.

11. The semiconductor device of claim 10, wherein the sheet semiconductor layers a first region of nanosheets at a first height and a second region of nanosheets at a second height, wherein the second height is less than the first height, the upper sheet portion that the first contact is in contact with is in the first region, and the lower sheet portion that the second contact is in contact with is in the second region.

12. The semiconductor device of claim 10, wherein the lower sheet portion includes a bottom sheet source/drain epitaxy material.

13. The semiconductor device of claim 12, wherein the extended epitaxial semiconductor region has a higher dopant concentration for n-type or p-type dopant than the bottom sheet source/drain epitaxy material.

14. The semiconductor device of claim 9, wherein the upper sheet portion of the source and drain regions is an upper sheet epitaxy semiconductor material that is doped to an n-type or p-type conductivity.

15. A method of forming a semiconductor device comprising:
forming a stack of sheet semiconductor layers;
forming source and drain regions on opposing sides of a channel region in the stack of sheet semiconductor layers;
forming a first contact to an upper sheet portion of the source and drain regions for the stack of sheet semiconductor layers;
epitaxially forming an extended epitaxial semiconductor region in contact with a lower sheet portion of the source and drain regions for the stack of sheet semiconductor layers; and
forming a second contact in direct contact with an upper surface of the extended epitaxial semiconductor region.

16. The method of claim 15, wherein the sheet semiconductor layers are nanosheets.

17. The method of claim 15, wherein the sheet semiconductor layers a first region of nanosheets at a first height and a second region of nanosheets at a second height, wherein the second height is less than the first height, the upper sheet portion that the first contact is in contact with is in the first region, and the lower sheet portion that the second contact is in contact with is in the second region.

18. The method of claim 15, wherein the upper sheet portion of the source and drain regions is an upper sheet epitaxy semiconductor material that is doped to an n-type or p-type conductivity.

19. The method of claim 18, wherein the upper sheet epitaxy semiconductor material and the extended epitaxial semiconductor region have a substantially same height from a supporting substrate underlying the stack of sheet semiconductor materials.

20. The method of claim 15 further comprising etching the upper surface of the extended epitaxial semiconductor region to provide a notch, wherein the notch provides a sidewall surface and base surface for the second contact to be formed in direct contact with.
